(19) United States
(12) Patent Application Publication
(10) Pub. No.: US 2023/0006158 A1
(43) Pub. Date: Jan. 5, 2023

(54) PROTECTIVE ENCAPSULATION OF SOLAR SHEETS

(71) Applicant: NANOFLEX POWER CORPORATION, Scottsdale, AZ (US)

(72) Inventors: Olga GRIFFITH, Scottsdale, AZ (US); Adam BARITO, Scottsdale, AZ (US)

(21) Appl. No.: 17/756,806

(22) PCT Filed: Dec. 3, 2020
(86) PCT No.: PCT/US2020/063131

§ 371 Date: Jun. 2, 2022

Related U.S. Application Data
(60) Provisional application No. 62/942,897, filed on Dec. 3, 2019.

(51) Int. Cl. H01L 51/44

(52) U.S. Cl. CPC H01L 51/448

(57) ABSTRACT

A photovoltaic device comprising: a substrate; a photovoltaic module comprising a plurality of photovoltaic cells disposed on the substrate; a top electrode and a bottom electrode incorporated into the photovoltaic module, wherein the top electrode and the bottom electrode are at least partially exposed; and a protective encapsulation covering at least an active area of the photovoltaic module, wherein the protective encapsulation comprises a) at least one vacuum-processed material having an evaporation temperature less than or equal to 1200° C. or b) at least one solution-processed metal oxide chosen from molybdenum oxide, tungsten trioxide, vanadium pentoxide, zinc oxide, nickel oxides, and titanium dioxide.

### CROSS-REFERENCE TO RELATED APPLICATION

This application claims the benefit of U.S. Provisional Application No. 62/942,897, filed Dec. 3, 2019, which is incorporated herein by reference in its entirety.

The present disclosure generally relates to photovoltaic modules comprising at least one electrically insulating and chemically inert protective layer.

A major challenge impeding commercialization of photovoltaic modules is their sensitivity to moisture and oxygen, which can lead to chemical and morphological degradation that can dramatically shortens performance lifetime. In order to mitigate the effects of moisture and oxygen, previous attempts were made to encapsulate photovoltaic modules through the use airtight packaging in inert environments. This encapsulation, however, could complicate the manufacturing process and increase costs. Another method to mitigate the effects of moisture and oxygen was through encapsulation with hot melt adhesives, epoxy adhesives, and/or pressure/temperature sensitive adhesives. Encapsulation with these adhesives, however, could lead to performance degradation.

To address these issues, the present disclosure is directed to at east one electrically insulating and chemically inert protective layer—referred herein as a protective encapsulant—that is disposed directly onto at least a portion of a completed photovoltaic module. The protective encapsulation of the present disclosure can eliminate the reaction of photovoltaic layers with air and therefore improve lifetime of photovoltaic module. In addition, the protective encapsulation of the present disclosure can prevent reactions between photovoltaic materials and existing encapsulation layers. Furthermore, the protective encapsulation of the present disclosure can encapsulate the photovoltaic device in air without degradation of the photovoltaic layers.

The protective encapsulation of the present disclosure can mitigate chemical compatibility problems of adhesives with the photovoltaic layers, such as organic photovoltaic (OPV) layers, and thus dramatically increase the variety of further encapsulations and laminations available for packaging of the photovoltaic devices. In addition, the materials to be used as protective encapsulants according to the present disclosure are inexpensive and can be deposited at a manufacturing scale.

The entire device, i.e., the photovoltaic module plus the protective encapsulation, can then be laminated/further encapsulated/packaged in air, thereby producing a photovoltaic with an extended lifetime and at a lower cost.

The protective encapsulation according to the present disclosure can be used on any of a plurality of photovoltaics devices to similarly isolate or protect the device to improve its performance, such as OPV modules. Additionally non-limiting examples of photovoltaics devices include III-Vs (such as gallium arsenide (GaAs), gallium indium phosphide (GaInP), and gallium aluminum arsenide (GaAlAs)), silicon, cadmium telluride (CdTe), copper indium gallium selenide (GIGS), quantum dots (OD), copper zinc tin sulfide (CZTS), and/or perovskites photovoltaic modules.

In certain embodiments, the present disclosure is directed to a photovoltaic device comprising: a substrate; a photovoltaic module comprising a plurality of photovoltaic cells disposed on the substrate; a top electrode and a bottom electrode incorporated into the photovoltaic module, wherein the top electrode and the bottom electrode are at least partially exposed; and a protective encapsulation covering at least an active area of the photovoltaic module; wherein the protective encapsulation comprises a) at least one vacuum-processed material having an evaporation temperature less than or equal to 1200° C. or b) at least one solution-processed metal oxide chosen from molybdenum oxide (MoOₓ), tungsten trioxide (WO₃), vanadium pentoxide (V₂O₅), zinc oxide (ZnO), nickel oxides (NiOₓ), and titanium dioxide (TiO₂).

In certain embodiments, the present disclosure is directed to an organic photovoltaic device comprising: a substrate; a photovoltaic module comprising a plurality of photovoltaic cells disposed on the substrate; a top electrode and a bottom electrode incorporated into the photovoltaic module, wherein the top electrode and the bottom electrode are at least partially exposed; and a protective encapsulation covering at least an active area of the photovoltaic module; wherein the protective encapsulation comprises at least one vacuum-processed material having an evaporation temperature less than or equal to 1200° C., wherein the at least one vacuum-processed material is chosen from MoO₃, WO₃, SiO₂, V₂O₅, AlF₃, LiF, MgF₂, bathophenanthroline, and 2,2′,2″-(1,3,5-Benzinetriyl)-tris(1-phenyl-1-H-benzimidazole).

In additional embodiments, the present disclosure is directed to an organic photovoltaic device comprising: a substrate; a photovoltaic module comprising a plurality of photovoltaic cells disposed on the substrate; a top electrode and a bottom electrode incorporated into the photovoltaic module; wherein the top electrode and the bottom electrode are at least partially exposed; and a protective encapsulation covering at least an active area of the photovoltaic module, wherein the protective encapsulation comprises at least one vacuum-processed metal oxide or metal fluoride chosen from MoO₃, WO₃, SiO₂, V₂O₅, AlF₃, LiF, and MgF₂.

In further embodiments, the present disclosure is directed to an organic photovoltaic device comprising: a substrate; a photovoltaic module comprising a plurality of photovoltaic cells disposed on the substrate; a top electrode and a bottom electrode incorporated into the photovoltaic module, wherein the top electrode and the bottom electrode are at least partially exposed; and a protective encapsulation covering at least an active area of the photovoltaic module, wherein the protective encapsulation comprises at least one solution-processed metal oxide chosen from molybdenum oxide (MoOₓ), tungsten trioxide (WO₃), vanadium pentoxide (V₂O₅), zinc oxide (ZnO), nickel oxides (NiOₓ), and titanium dioxide (TiO₂).

Other embodiments of the present disclosure are set forth below.

It is to be understood that both the foregoing general description and the following detailed description are exemplary and explanatory only and are not restrictive of the invention, as claimed.

### BRIEF DESCRIPTION OF THE DRAWINGS

The accompanying figures, which are incorporated in and constitute a part of this specification, illustrate several embodiments of the invention and together with the description, serve to explain the principles of the invention,

FIGS. 1A-1C are cross-sectional views of a photovoltaic device with differing degrees of coverage provided by a protective encapsulation.

FIGS. 2A-2C are cross-sectional views of a photovoltaic device with differing degrees of coverage provided by two protective encapsulations.

FIGS. 3A-3D depict characteristics of a protective encapsulation layer disposed onto an organic photovoltaic device.

The drawings described herein are for illustrative purposes only of selected embodiments and not all possible implementations, and are not intended to limit the scope of the present disclosure. Corresponding reference numerals indicate corresponding parts throughout the several views of the drawings.

### DETAILED DESCRIPTION

Certain embodiments of the present disclosure are directed to a photovoltaic device comprising: a substrate; a photovoltaic module comprising a plurality of photovoltaic cells disposed on the substrate; a top electrode and a bottom electrode incorporated into the photovoltaic module, wherein the top electrode and the bottom electrode are at least partially exposed; and a protective encapsulation covering at least an active area of the photovoltaic module, wherein the protective encapsulation comprises a) at least one vacuum-processed material having an evaporation temperature less than or equal to 1200° C. orb) at least one solution-processed metal oxide chosen from molybdenum oxide (MoOₓ), tungsten trioxide (WO₃), vanadium pentoxide (V₂O₅), zinc oxide (ZnO), nickel oxides (NiOₓ), and titanium dioxide (TiO₂). In further embodiments, the photovoltaic is an OPV.

As used herein, the term “active area” refers to the area that generates photocurrent in a photovoltaic device.

The photovoltaic devices according to the present disclosure, such as for example the OPV devices, can be used in many downstream markets, including but not limited to agriculture, indoor farming, ecology, livestock tracking, home automation, internet of things, indoor light harvesters, outdoor light harvesters, recreation, wearable devices, smartphones/tablets/computers/watches, jewelry, energy infrastructure, medical, medical monitoring devices and biomedical patches, retail, cold chain, food transport/packaging/storage/preparation/serving, logistics, air/land/water transportation, aerospace, shipping, asset tracking, location/movement/vibration monitoring, architecture, military, defense and surveillance, radar and remote sensing, modular power harvesting and/or radio device, building/home monitoring, tamper resistant monitoring, alert systems, automation, automotive, and building integrated photovoltaics.

According to the present disclosure, the photovoltaic device can be comprised of series and/or parallel photovoltaic cells disposed on the substrate and organized into a module with current collection and encapsulation for long life. The photovoltaic device also comprises a top electrode and a bottom electrode. The photovoltaic device may comprise one or more junctions disposed sequentially.

In some embodiments, a photovoltaic device may be fabricated in custom shapes to serve functional and/or aesthetic purposes e.g., a polygon, circle, or any shape made from combinations of straight and curved edges.

In some embodiments, additional layers may be disposed on a photovoltaic device to enhance its performance, lifetime, manufacturability, aesthetics, and/or add functionality. These layers may be semiconductor, metal, dielectric, and/or insulating layers. In some embodiments, the additional layers added to a photovoltaic may include, but are not limited to, anti-reflection coatings, ultra-violet protection layers, superlattices, Bragg reflectors, infrared reflective layers, ceramics layers, oxide layers, metal oxide layers, micropatterned layers, quantum dots, growth buffer and cap layers, and metamorphic layers.

A photovoltaic may consist of organic photovoltaic (OPV) cells, III-Vs (such as but not limited to gallium arsenide (GaAs), gallium indium phosphide (GaInP), gallium aluminum arsenide (GaAlAs)), silicon, cadmium telluride (CdTe), copper indium gallium selenide (GIGS), quantum dots (QD), copper zinc tin sulfide (CZTS), and/or perovskites photovoltaic cells.

Organic photovoltaic cells have many potential advantages over inorganic photovoltaic cells due to their nontoxic nature, relatively small energy investment for fabrication, conformability to non-planar surfaces, and compatibility with large-area, high-throughput manufacturing processes. In some embodiments, OPV modules may be manufactured to be semi-transparent, highly reflective, or opaque. Semi-transparent OPV modules may be achieved through using semi-transparent conductive materials, such as indium tin oxide or thin metal, for both top and bottom electrodes. Reflectivity and hue may be controlled via organic material selection and thickness of the organic layers in the OPV module. OPV modules may contain polymers and/or organic molecules (including pure carbon compounds) as photo-active materials. Polymer-based and/or organic-molecule-based OPV modules may be solution-processed, requiring carrier solvents and manufacturing methods such as, but not limited to, blade coating, spin coating, and printing. Some small molecule OPV modules may also be manufactured through vacuum deposition. In some embodiments, OPV module manufacturing may involve small molecule materials deposited via vacuum thermal evaporation, organic vapor jet printing, or organic vapor phase deposition. Other manufacturing methods may include, atomic layer deposition, drop casting, inkjet printing, slot-die coating, dip coating, bar coating, sol-gel, and photo-crosslinking.

Organic photovoltaic may include materials such as organic molecules, pure carbon compounds, and/or polymers.

In certain embodiments the protective encapsulation can be disposed onto the photovoltaic in vacuum. In some embodiments, the protective encapsulation can be disposed onto the photovoltaic in environments with pressure ranging from low vacuum to atmospheric (above 1 mTorr). In further embodiments the protective encapsulation may be disposed onto a photovoltaic by vacuum deposition methods, including but not limited to, vacuum thermal evaporation, atomic layer deposition, chemical vapor deposition, vapor phase deposition, and physical vapor deposition.

Vacuum-processable protective encapsulation materials include but are not limited to glasses and metal oxides and/or metal fluorides with evaporation temperatures less than or equal to 1200° C., including but not limited to MoO₃, WO₃, SiO₂, V₂O₅, AlF₃, LIF, MgF₂, bathophenanthroline, and 2,2′,2″-(1,3,5-Benzinetriyl)-tris(1-phenyl-1-H-benzimidazole). In further embodiments, additional materials can be disposed onto the vacuum-processable protective encapsulation materials. These additional materials include metals and/or metal alloys, such as, for example, Al, Ag, Cu, and Au.

In other embodiments, the protective encapsulation may be disposed onto a photovoltaic by solution processing methods, including but not limited to, sol-gel, spraying, brushing, spin coating, blade coating, dip coating, slot-die coating, bar coating, printing, and syringe/pipette/dropper dispensing. Solution-processable protective encapsulation materials include but are not limited to MoO₃, WO₃, V₂O₅, ZnO, NiOₓ, and TiO₂. In further embodiments, additional materials can be disposed onto the solution-processable protective encapsulation materials. These additional materials include metals and/or metal alloys, such as, for example, Al, Ag, Cu, and Au.

The protective encapsulation materials disclosed herein may be disposed sequentially or with intermediate layers. In addition, the protective encapsulation layer maybe be disposed via batch (sheet-to-sheet) or continuous (roll-to-roll) processes.

In some embodiments, the protective encapsulation may be disposed onto a photovoltaic in-situ, as part of fabrication processes of photovoltaic components. In other embodiments, the protective encapsulation may be disposed ex-situ, after fabrication of a photovoltaic is completed.

In certain embodiments, the protective encapsulants may include but are not limited to electrically insulating materials, glasses, metal oxides, metal fluorides, metals, and/or any combination of them.

In some embodiments, the photovoltaic is flexible with a low stiffness <5 N/m that contain, but not limited to, materials with Glass Young's modulus<50 GPa. In other embodiments, the photovoltaic is rigid.

The substrates according to the present disclosure can include, but are not limited to, glass, willow glass, polyethylene terephthalate, acrylic, polycarbonate, polyimides, silicon, mica, amorphous/crystalline/polycrystalline aluminum oxide and/or sapphire, silicon dioxide, and metal foils/sheets.

In certain embodiments, the present disclosure is directed to an organic photovoltaic device comprising: a substrate; a photovoltaic module comprising a plurality of organic photovoltaic cells disposed on the substrate; a top electrode and a bottom electrode incorporated into the photovoltaic odule, wherein the top electrode and the bottom electrode are at least partially exposed; and a protective encapsulation covering at least an active area of the organic photovoltaic module, wherein the protective encapsulation comprises a) at least one vacuum-processed material having an evaporation temperature less than or equal to 1200° C. or b) at least one solution-processed metal oxide chosen from molybdenum oxide (MoOₓ), tungsten trioxide (WO₃), vanadium pentoxide (V₂O₅), zinc oxide (ZnO), nickel oxides (NiOₓ), and titanium dioxide (TiO₂).

In further embodiments; the protective encapsulation covering the at least the active area of the organic photovoltaic module comprises at least one vacuum-processed material having an evaporation temperature less than or equal to 1200° C., wherein the at least one vacuum-processed material is chosen from MoO₃, WO₃, SiO₂, V₂O₅, AlF₃, LiF, MgF₂, bathophenanthroline, and 2,2′,2″-(1,3,5-Benzinetriyl)-tris(1-phenyl-1-H-benzimidazole). In other embodiments, the protective encapsulation covering the active area of the organic photovoltaic module comprises at least one vacuum-processed metal oxide or metal fluoride chosen from MoO₃, WO₃, SiO₂, V₂O₅, AlF₃, LiF, and MgF₂. In additional embodiments, the protective encapsulation covering the active area of the organic photovoltaic module comprises at least one solution-processed metal oxide chosen from molybdenum oxide (MoOₓ), tungsten trioxide (WO₃), vanadium pentoxide (V₂O₅), zinc oxide (ZnO), nickel oxides (NiOₓ), and titanium dioxide (TiO₂).

In some embodiments, optional encapsulation and/or packaging may be added to cover entire photovoltaic device. Optional encapsulation may include but is not limited to lamination, potting coating and/or conformal coating. This optional encapsulation and/or packaging may provide protection against, for example but not limited to, oxygen, moisture, rain, hail, snow, wind, thermal gradients/changes between −40° C. and 85° C., storms, hurricanes, fires, scratching, scraping, fracturing, cracking, and shattering.

In some embodiments optional packaging may cover a photovoltaic using rigid and/or flexible barrier materials such as but not limited to glasses, willow glass, metal foils, plastics, polymers, acrylics, composite films, plexiglass, polyethylene terephthalate, polycarbonate, polyimides, silicon, mica, amorphous/crystalline/polycrystalline aluminum oxide and/or sapphire, silicon dioxide, etc. These barrier materials may be attached to a photovoltaic using, for example but not limited to, epoxies, resins, UV-curable epoxies/resins/adhesives, thermally activated adhesives, pressure activated adhesives, temperature and pressure activated adhesives, etc.

Lamination may include but is not limited to plastics, glass, metals, silicones, elastomers. Lamination can be achieved, for example but not limited to, thermal/pressure/vacuum lamination, UV curing, vacuum lamination, flame lamination, hot melt lamination, extrusion lamination, dry-bond lamination, wet-bond lamination, and solventless lamination.

Potting/conformal coating may include but is not limited to urethane, parylene, polymers, resins, epoxies, acrylic, paints, tapes, fluorocarbon, nano coatings, hybrid coatings, water-based coating, UV cure coating.

The encapsulated photovoltaic can be integrated into an electronic device. In some embodiments, the electronics device may be a sensor, a stand-alone energy harvester, building-integrated photovoltaics, a portable charging unit, or radio unit.

In other embodiments, the electronics devices may contain components of supercapacitors, fuel cells, thermoelectric device, light-emitting devices, LEDs, power management chips, logic circuits, microprocessors, microcontroller, integrated circuits, resistors, capacitors, transistors, inductors, diodes, semiconductors, optoelectronic devices, memristor, MEMS device, varistor, antennas, transducers, crystals, resonators, terminals, vacuum tubes, optical detectors/emitters, heaters, circuit breaker, fuse, relay, spark gap, heat sink, motor, displays (such as but not limited to LCD, LED, ELD, AMOLED, OLED, QLED, CRT, VFD, DLP, IMOD, DMS, plasma, neon, filament), touch screens, external connectors, data storage, piezo devices, speakers, microphones, security chips, and user input controls such as but not limited to buttons, knobs, sliders, switches, joystick, directional-pads, keypad, and pressure/touch sensor.

A sensor may measure, for example but is not limited to: humidity, CO₂, light level, vapor pressure deficit, heat index, water pH, soil moisture, volumetric soil moisture content, soil pH, accelerometer, temperature, pressure, gas sensing, GPS, UWB trilateration, parametric sensing, CO, oxygen, total volatile organic compounds, chemical, contaminants, conductivity, resistivity, current sensing/measuring, electrical activity, metal detecting, evapotranspiration, water usage, salinity, pest control, climate monitoring, stem diameters, radiation, rain, snow, wind, lightning, soil nutrients, occupancy, position/status, smoke, fluid leaks, power failure, total dissolved solids, flood, motion, door/window motion, photogate, touch, Haptic, displacement, level, acoustic/sound/vibration/frequency, air flow, Hall effect, fuel level, fluid level, radar, torque, speed, tire pressure, chemicals, infrared, ozone, magnetic, radio direction finder, air pollution, moisture detection, seismometer, airspeed, depth, altimeter, freefall, position, angular rate, shock, tilt, velocity, inertial, force, stress, strain, weight, flame, proximity/presence, stretch, heartbeat, heart rate, blood glucose, blood oxygen, insulin, body temperature, medical chemical detection, blood pressure, sleep monitoring, respiration rate, lactic acid, hydration, cholesterol, electrocardiogram, electroencephalogram, electromyogram, hemoglobin, and anemia.

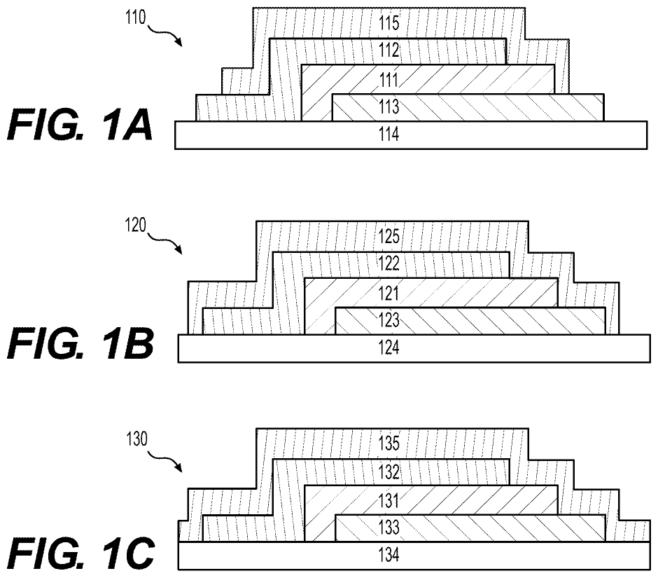

FIGS. 1A-1C are cross-sectional views of a photovoltaic device with differing degrees of coverage provided by a protective encapsulation. As illustrated in FIG. 1A, photovoltaic device 110 may include photovoltaic module 111, top contact 112, bottom contact 113, substrate 114, and protective encapsulation 115. Photovoltaic module 111 may be disposed on substrate 114 and may include top contact 112 and bottom contact 113. Top contact 112 and bottom 113 may be positive and negative or negative and positive, respectively. Top contact 112 and bottom contact 113 may be arranged such that both may be exposed to be able to complete a connection with an electronics device.

Substrate 114 can comprise any known substrates including plastics, glass, willow glass, polyethylene terephthalate, acrylic, polycarbonate, polyimide, silicon, mica, amorphous/crystalline/polycrystalline aluminum oxide and/or sapphire, silicon dioxide, elastomer, resin, and/or metal foils/sheets. In some embodiments, photovoltaic module 111 and substrate 114 may be encapsulated before integration with electronics via protective encapsulation 115.

Manufacturing methods for photovoltaic device 110 may include, but are not limited to, electron-beam deposition, sputtering, vacuum thermal evaporation, vapor phase deposition, chemical vapor deposition, vapor phase deposition, physical vapor deposition, sol-gel, spraying, brushing, syringe/pipette/dropper dispensing, vapor jet printing, atomic layer deposition, drop casting, blade coating, screen printing, inkjet printing, slot-die coating, dip coating, bar coating, spin coating, painting, and/or soldering.

In some embodiments, photovoltaic module 111 may include photovoltaic junctions (not shown), also referred to as photovoltaic sub-cells, disposed on substrate 114. Photovoltaic module 111 may consist of organic photovoltaic (OPV) cells, Ill-Vs (such as but not limited to gallium arsenide (GaAs), gallium indium phosphide (GaInP), gallium aluminum arsenide (GaAlAs)), silicon, cadmium telluride (CdTe), copper indium gallium selenide (GIGS), quantum dots (OD), copper zinc tin sulfide (CZTS), and/or perovskites photovoltaic cells. In some embodiments, parts or all of photovoltaic module 111 may also be referred to as the “active area,” the active area being defined as the area that generates photocurrent in a photovoltaic device (e.g., photovoltaic device 110).

In some embodiments, photovoltaic device 110 may be made flexible. A flexible photovoltaic device 110 may have a low stiffness (e.g., less than 5 N/m) and may contain materials with a Glass Young's modulus smaller than 50 GPa. In some embodiments, a flexible photovoltaic module 111 may be disposed onto a flexible substrate 114, wherein the flexible substrate 114 may be made of polymers/thermoplastics (e.g., polyimide and polyester films, polyethylene terephthalate, polypropylene, polycarbonate), composite/multilayered films, willow glass, acrylic, metal/metal alloy foils, paper, fabrics/textiles, and/or other flexible materials. In other embodiments, photovoltaic device 110 may be rigid.

In some embodiments, photovoltaic module 111 may be optimized for any light spectrum, such as sunlight or artificial light (e.g., LED, fluorescent, incandescent, grow lights, neon lights, mercury vapor, metal halide, high-intensity discharge, bioluminescent, chemiluminescent), to increase the energy harvesting from solar for a target spectrum. For example, for a given light spectrum, the optimization could target a specific level of light, ranging from 1 lux to 150,000 lux. In some embodiments, photovoltaic module 111 may be optimized for indoor light, ensuring that whether photovoltaic device 110 is indoors or outdoors, there will be enough light to power photovoltaic device 110 even if photovoltaic module 111 is not optimized for outdoor light.

In some embodiments, optimizing photovoltaic module 111 may involve changing layers structure, changing layers thickness, and/or adding layers. For example, photovoltaic module 111 may be highly tunable to the light spectrum in varying applications. Internally, color and transparency of photovoltaic module 111 may be tuned by increasing or decreasing device layer thicknesses, choosing photoactive materials based on their spectral absorption properties, varying the ratio of photoactive materials, and adding or removing layers. Externally, photovoltaic module 111 may be tuned to a specific light spectrum using anti-reflective coatings, distributed Bragg reflectors, micro-patterning, and other light-trapping structures. In some embodiments, photovoltaic module 111 may be engineered such that its absorption spectrum may accept the emission spectrum of the light source. This may be tuned by varying the bandgap of an individual sub-cell (e.g., one of the junctions of photovoltaic module 111), or by adding multiple junctions to photovoltaic device 110 such that the combined absorption spectrum of photovoltaic module 111 is matched to the light source—thereby increasing the efficiency of photovoltaic module 111. For example, in inorganic photovoltaic cells, elements may be added to the base photovoltaic cell (e.g., adding N to GaAs) to adjust the bandgap.

In some embodiments, photovoltaic module 111 may be fabricated in custom shapes to serve functional and/or aesthetic purposes. Substrate 114, photovoltaic module 111, and protective encapsulation 115 may take any shape, e.g., a polygon, circle, or any shape made from combinations of straight and curved edges. In some embodiments, additional layers may be disposed on photovoltaic module 111 to enhance its performance, lifetime, manufacturability, aesthetics, and/or add functionality. These layers may be semiconductor, metal, dielectric, and/or insulating layers.

In some embodiments, the electronics device connected to photovoltaic device 110 may include radios such as Bluetooth Low Energy (BLE), long-term evolution (LTE) or cellular, Wi-Fi or IEEE 802.11, long range (LoRa), ultra-wideband (UWB), infrared (IR), radio frequency identification (RFID), or other Industrial, scientific, and medical band (ISM-band) radios. Different radios may be used for different applications. For example, some radios which have a shorter range and require lower power may be used indoors (e.g., BLE) where the signal range does not have to be long, while others which have a longer range and require more power may be used outdoors (e.g., LoRa radio for farms, or LTE for moving vehicles).

In some embodiments, the electronics device may attach the following components to a backside or topside of photovoltaic module 111 enabled by exposed top contact 112 and bottom contact 113: batteries, supercapacitors, fuel cells, thermoelectric devices, light-emitting devices, LEDs, power management chips, logic circuits, microprocessors, microcontrollers, integrated circuits, resistors, capacitors, transistors, inductors, diodes, semiconductors, optoelectronic devices, memristors, micro-electromechanical systems (MEMS) devices, varistors, antennas, transducers, crystals, resonators, terminals, vacuum tubes, optical detectors/emitters, heaters, circuit breakers, fuses, relays, spark gaps, heat sinks, motors, displays (such as, but not limited to, liquid crystal displays (LCD), light-emitting diode (LED), microLED, electroluminescent displays (ELD), electrophoretic displays, active matrix organic light-emitting diode (AMOLED), organic light-emitting diode (OLED), quantum dot (OD), quantum light-emitting diode (QLED), cathode ray tube (CRT), vacuum florescent displays (VFD), digital light processing (DLP), interferometric modulator displays (IMOD), digital microshutter displays (DMS), plasma, neon, filament, surface-conduction electron-emitter displays (SED), field emission displays (FED), Laser TV, and carbon nanotubes), touch screens, external connectors, data storage, piezo devices, speakers, microphones, security chips, and user input controls such as, but not limited to buttons, knobs, sliders, switches, joysticks, directional-pads, keypads, and pressure/touch sensors.

In some embodiments, the electronics components may be flexible, or they may be rigid components such as die electronics components or larger chips, consistent with disclosed embodiments. Rigid components may be placed on a flexible substrate 112, maintaining the overall flexibility of photovoltaic device 110.

Exposed top contact 112 and bottom contact 113 may be electrical connected to the electronics device by any means, including but not limited to soldering, ultrasonic soldering, conductive epoxy, conductive paste, conductive paints, spot welding, welding, wire bonding, printed conductive inks, mechanical contact, nanowire meshes, graphene, and graphite. The electronics device may be attached to photovoltaic module 111 by a method including, but not limited to, robotic pick-and-place of components, manually attaching components, attaching components via adhesives, and/or attaching a printed electronics or substrate 114 with the electronics device. Circuits may be assembled by printing, painting, using electrical connections, and/or any method for manufacturing a circuit.

In some embodiments, protective encapsulation 115 may be disposed onto one or more of the substrate, the photovoltaic module, the top electrode, and the bottom electrode in a vacuum and/or in environments with pressure ranging from low vacuum (e.g., 1 mTorr) to atmospheric. Protective encapsulation 115 may be thinner, as thick, or thicker than substrate 114, photovoltaic module 111, top electrode 112, and bottom electrode 113.

As shown in FIG. 1A, protective encapsulation 115 may be disposed such that only photovoltaic module 111 is covered by protective encapsulation 115, i.e., protective encapsulation 115 covers only the active area of photovoltaic device 110. In FIG. 1B, instead, protective encapsulation 125 may be disposed such that photovoltaic module 121, top contact 122, and bottom contact 123 are covered by protective encapsulation 125. Alternatively, FIG. 1C depicts a protective encapsulation 135 which may be disposed such that photovoltaic module 131, top contact 132, bottom contact 133, and substrate 134 are all covered by protective encapsulation 135. FIGS. 1B and 1C both depict protective encapsulations 125 and 135 which cover more than the active area of photovoltaic devices 120 and 130.

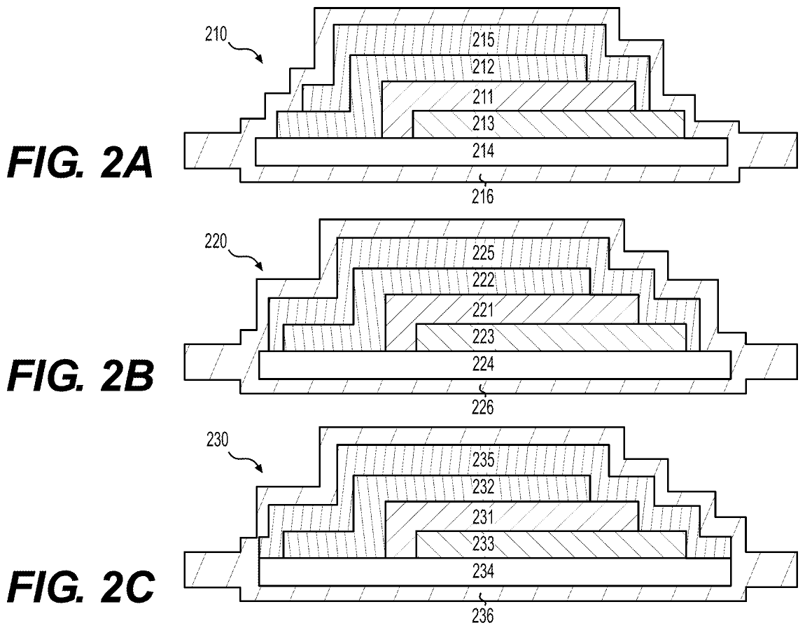

Turning now to FIGS. 2A-2C, and first to FIG. 2A, once protective encapsulation 215 is disposed onto photovoltaic module 211, photovoltaic device 210 may be encapsulated by an optional encapsulation 216. Optional encapsulation 216 may include, but is not limited to, lamination and potting/conformal coating. Lamination may include, but is not limited to, plastics, glass, metals, silicones, and elastomers. Lamination may be achieved, for example, through thermal/pressure/vacuum lamination, UV curing, vacuum lamination, flame lamination, hot melt lamination, extrusion lamination, dry-bond lamination, wet-bond lamination, solventless lamination, and/or any method for sealing photovoltaic device 210 with a material. Potting/conformal coating may include, but is not limited to, urethane, parylene, polymers, resins, epoxies, acrylic, paints, tapes, fluorocarbon, nano coatings, hybrid coatings, water-based coating, solvent-based coating, UV cure coating. Optional encapsulation 216 may also be applied by, for example, spraying, brushing, vacuum coating, vacuum sealing, vacuum depositing, blade coating, screen printing, dipping, syringe/pipette/dropper dispensing, curing, and selective coating.

Photovoltaic device 210, having undergone the manufacturing process, may be self-contained or may enable attachment to other devices through exposed leads and/or external connectors. In some embodiments, an adhesive or adhesive strip may be disposed on the backside or topside of the lamination to enable simple installation of device 210. This may, for example, enable photovoltaic device 210 to include a label, sensor, and/or other electronics devices which may need to be placed on boxes, shipping packages, and/or other surfaces which would benefit from an easily-applicable device.

FIG. 2A depicts an optional encapsulation 216 covering a photovoltaic device 210 which includes a protective encapsulation 215 covering photovoltaic module 211, i.e., protective encapsulation 215 covers only the active area of photovoltaic device 210. Meanwhile, FIG. 2B depicts an optional encapsulation 226 covering a photovoltaic device 220 which includes a protective encapsulation 225 covering photovoltaic module 221, top contact 222, and bottom contact 223. FIG. 2C, instead, depicts an optional encapsulation 236 covering a photovoltaic device 230 which includes a protective encapsulation 235 covering photovoltaic module 231, top contact 232, bottom contact 233, and substrate 234. FIGS. 2B and 2C both depict protective encapsulations 225 and 235 which cover more than the active area of photovoltaic devices 220 and 230.

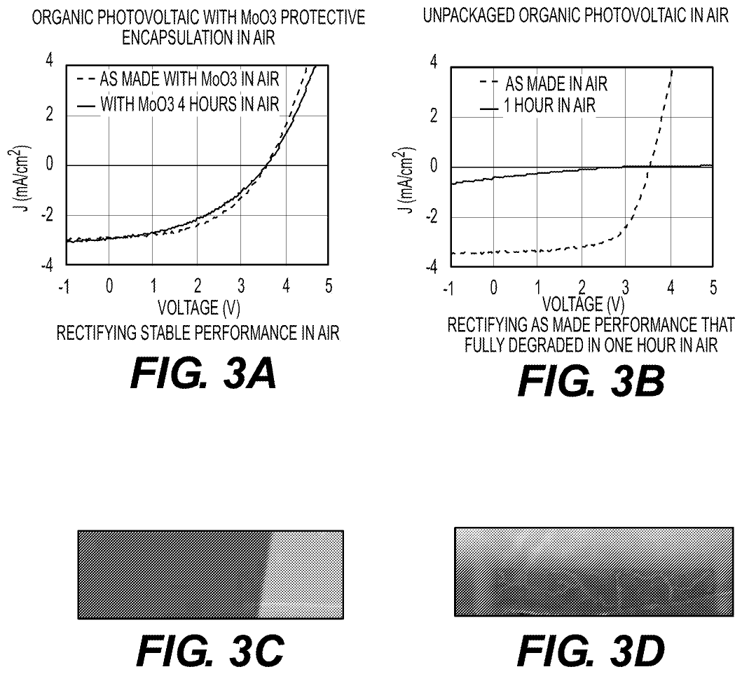

As an example, FIGS. 3A-3D illustrate a vacuum-processable MoO₃ layer (e.g., protective encapsulation 215) successfully disposed onto an organic photovoltaic (OPV) module (e.g., photovoltaic module 211) to prevent chemical degradation of photovoltaic components caused by optional packing (e.g., optional encapsulation 216), and to provide protection from oxygen and moisture during optional packaging process. As shown in FIG. 3A, the MoO₃ protective encapsulation allows an OPV module to have a stable performance in air for at least 4 hours. However, if the MoO₃ layer were not applied, as in FIG. 3B, the OPV module's active components would become insulators due to reactions with ambient air, and current-voltage rectification behavior would be lost within an hour of air exposure.

Another advantage of applying the protective encapsulation is providing protection from degradation due to parasitic reactions with optional encapsulations, such as an epoxy adhesive. Namely, when a protective encapsulation is disposed onto the photovoltaic device prior to the optional encapsulation, the organic components of the photovoltaic device were preserved, as illustrated in Fla 3C, and parasitic reactions prevented. In contrast, when disposing an epoxy adhesive onto a photovoltaic device without a protective encapsulation, organic components of the photovoltaic device were dissolved by the epoxy adhesive during the optional encapsulation process, as seen in FIG. 3D.

What is claimed is:

1. A photovoltaic device comprising:
a substrate;
a photovoltaic module comprising a plurality of photovoltaic cells disposed on the substrate;
a top electrode and a bottom electrode incorporated into the photovoltaic module, wherein the top electrode and the bottom electrode are at least partially exposed; and
and a protective encapsulation covering at least an active area of the photovoltaic module, wherein the protective encapsulation comprises:
a) at least one vacuum-processed material having an evaporation temperature less than or equal to 1200° C. or
b) at least one solution-processed metal oxide chosen from molybdenum oxide (MoOₓ), tungsten trioxide (WO₃), vanadium pentoxide (V₂O₅), zinc oxide (ZnO), nickel oxides (NiOₓ), and titanium dioxide (TiO₂).

2. The photovoltaic device of claim 1, wherein the protective encapsulation covering the active area of the organic photovoltaic module comprises at least one vacuum-processed material having an evaporation temperature less than or equal to 1200° C., wherein the at least one vacuum-processed material is chosen from MoO₃, WO₃, SiO₂, V₂O₅, AlF₃, LiF, MgF₂, bathophenanthroline, and 2,2′,2″-(1,3,5-Benzinetriyl)-tris(1-phenyl-1-H-benzimidazole).

3. The photovoltaic device of claim 1, wherein the protective encapsulation covering the active area of the organic photovoltaic module comprises at least one vacuum-processed metal oxide or metal fluoride chosen from MoO₃, WO₃, SiO₂, V₂O₅, AlF₃, LiF, and MgF₂.

4. The photovoltaic device of claim 1, wherein the protective encapsulation covering the active area of the organic photovoltaic module comprises at least one solution-processed metal oxide chosen from molybdenum oxide (MoOₓ), tungsten trioxide (WO₃), vanadium pentoxide (V₂O₅), zinc oxide (ZnO), nickel oxides (NiOₓ), and titanium dioxide (TiO₂).

5. The photovoltaic device of claim 1, further comprising one or more junctions disposed sequentially.

6. The photovoltaic device of claim 1, wherein the plurality of photovoltaic cells comprises one or more of organic photovoltaic (OPV) cells, Ill-V semiconductors, silicon, cadmium telluride (CdTe), copper indium gallium selenide (CIGS), quantum dots (OD), copper zinc tin sulfide (CZTS), and perovskites photovoltaic cells.

7. The photovoltaic device of claim 1, wherein the device is an organic photovoltaic device comprising a plurality of organic photovoltaic cells

8. The photovoltaic device of claim 7, wherein the OPV cells comprise one or more of organic molecules, pure carbon compounds, and polymers.

9. The photovoltaic device of claim 1, wherein the photovoltaic device is flexible with a low stiffness.

10. The photovoltaic device of claim 9, further comprising materials with a Glass Young's modulus less than 50 GPa.

11. The photovoltaic device of claim 1, wherein the photovoltaic device is rigid.

12. The photovoltaic device of claim 1, wherein the substrate comprises one or more of glass, willow glass, polyethylene terephthalate, acrylic, polycarbonate, polyimides, silicon, mica, amorphous aluminum oxide, crystalline aluminum oxide, polycrystalline aluminum oxide, amorphous sapphire, crystalline sapphire, polycrystalline sapphire, silicon dioxide, metal foils, and metal sheets.

13. The photovoltaic device of claim 1, further comprising an optional encapsulation covering the entire photovoltaic device.

14. The photovoltaic device of claim 13, wherein the optional encapsulation comprises one or more of lamination, potting coating, and conformal coating.

15. The photovoltaic device of claim 14, wherein the lamination comprises one or more of plastics, glasses, metals, silicones, and elastomers.

16. The photovoltaic device of claim 14, wherein the lamination is achieved by one or more of thermal lamination, pressure lamination, vacuum lamination, UV curing, flame lamination, hot melt lamination, extrusion lamination, dry-bond lamination, wet-bond lamination, and solventless lamination.

17. The photovoltaic device of claim 14, wherein the potting coating comprises one or more of urethane, parylene, polymers, resins, epoxies, acrylics, paints, tapes, fluorocarbon, nano coatings, hybrid coatings, water-based coatings, and UV cure coating.

18. The photovoltaic device of claim 14, wherein the conformal coating comprises one or more of urethane, parylene, polymers, resins, epoxies, acrylics, paints, tapes, fluorocarbon, nano coatings, hybrid coatings, water-based coatings, and UV cure coating.

19. The photovoltaic device of claim 13, wherein the optional encapsulation comprises flexible barrier materials, the flexible barrier materials comprising one or more of glasses, willow glasses, metal foils, plastics, polymers, acrylics, composite films, plexiglass, polyethylene terephthalate, polycarbonate, polyimides, silicon, mica, amorphous aluminum oxide, crystalline aluminum oxide, polycrystalline aluminum oxide, amorphous sapphire, crystalline sapphire, polycrystalline sapphire, and silicon dioxide.

20. The photovoltaic device of claim 19, wherein the flexible barrier materials are attached to the photovoltaic device through the use of one or more of epoxies, resins, UV-curable epoxies, UV-curable resins, UV-curable adhesives, thermally-activated adhesives, pressure-activated adhesives, and temperature-and-pressure-activated adhesives.

21. The photovoltaic device of claim 1, wherein the protective encapsulation is as thick or thicker than the substrate, the photovoltaic module, the top electrode, and the bottom electrode.

22. The photovoltaic device of claim 1, wherein the protective encapsulation is disposed onto one or more of the substrate, the photovoltaic module, the top electrode, and the bottom electrode in a vacuum.

23. The photovoltaic device of claim 1, wherein the protective encapsulation is disposed onto one or more of the substrate, the photovoltaic module, the top electrode, and the bottom electrode in environments with pressure ranging from low vacuum to atmospheric.

24. The photovoltaic device of claim 1, wherein the protective encapsulation is disposed onto one or more of the substrate, the photovoltaic module, the top electrode, and the bottom electrode ex-situ, after fabrication of the photovoltaic device is complete.

25. The photovoltaic device of claim 1, wherein the photovoltaic device is integrated into an electronics device.
